(19) United States
(12) Patent Application Publication
(10) Pub. No.: US 2024/0413235 A1
(43) Pub. Date: Dec. 12, 2024

(54) NITRIDE SEMICONDUCTOR MODULE

(71) Applicant: ROHM CO., LTD., Kyoto (JP)

(72) Inventor: Hirotaka OTAKE, Kyoto (JP)

(73) Assignee: ROHM CO., LTD., Kyoto (JP)

(21) Appl. No.: 18/665,627

(22) Filed: May 16, 2024

(30) Foreign Application Priority Data
Jun. 9, 2023 (JP) 2023-095603

(51) Int. Cl. H01L 29/778; H01L 23/00; H01L 23/31; H01L 23/495; H01L 29/20

(52) U.S. Cl. CPC H01L 29/7786; H01L 29/2003; H01L 23/3121; H01L 23/4951; H01L 24/05; H01L 24/06; H01L 24/45; H01L 24/48; H01L 2224/05553; H01L 2224/05554; H01L 2224/05583; H01L 2224/05584; H01L 2224/05624; H01L 2224/05644; H01L 2224/05647; H01L 2224/05655; H01L 2224/05666; H01L 2224/05686; H01L 2224/06051; H01L 2224/45124; H01L 2224/45144; H01L 2224/45147; H01L 2224/48137; H01L 2224/48245; H01L 2924/0132; H01L 2924/04941; H01L 2924/1033; H01L 2924/13064; H01L 2924/1426

(57) ABSTRACT

A nitride semiconductor module includes a chip including at least one transistor, wherein the chip includes: a semiconductor substrate including a substrate upper surface and a substrate lower surface facing an opposite side of the substrate upper surface; an electron transit layer formed over the substrate upper surface of the semiconductor substrate and made of GaN; and an electron supply layer formed over the electron transit layer and made of GaN having a larger band gap than the electron transit layer, wherein the at least one transistor includes a gate electrode, a source electrode, and a drain electrode, which are formed over the electron supply layer, and wherein the semiconductor substrate is a GaN substrate having a thickness of 100 μm or less.

### CROSS-REFERENCE TO RELATED APPLICATION

This application is based upon and claims the benefit of priority from Japanese Patent Application No. 2023-095603, filed on Jun. 9, 2023, the entire contents of which are incorporated herein by reference.

### TECHNICAL FIELD

The present disclosure relates to a nitride semiconductor module.

### BACKGROUND

Currently, a high electron mobility transistor (HEMT) using a Group III nitride semiconductor such as a gallium nitride (GaN) semiconductor or the like (hereinafter, sometimes referred simply as a “nitride semiconductor”) is being commercialized. The HEMT uses a two-dimensional electron gas (2DEG) formed near an interface of a semiconductor heterojunction as a conductive path (channel). A power device using the HEMT is recognized as a device that enables a lower on-resistance, higher speed operation and higher frequency operation than a typical silicon (Si) power device.

For example, in the related art, a nitride semiconductor device includes a silicon substrate, an electron transit layer made of a gallium nitride (GaN) layer, and an electron supply layer made of an aluminum gallium nitride (AlGaN) layer. A 2DEG is formed in the electron transit layer near the interface of the heterojunction between the electron transit layer and the electron supply layer. Further, in the nitride semiconductor device of the related art, a gate layer (e.g., a p-type GaN layer) containing an acceptor type impurity is provided over the electron supply layer and directly below a gate electrode. According to this configuration, in a region directly below the gate layer, the gate layer raises a band energy of a conduction band near the interface of the heterojunction between the electron transit layer and the electron supply layer, causing the channel directly below the gate layer to disappear to realize a normally-off state.

### BRIEF DESCRIPTION OF DRAWINGS

The accompanying drawings, which are incorporated in and constitute a part of the specification, illustrate embodiments of the present disclosure.

FIG. 1 is a schematic plan view of an exemplary nitride semiconductor module according to a first embodiment.

FIG. 2 is a cross-sectional view taken along line 2-2 in FIG. 1.

FIG. 3 is an exemplary schematic plan view of a transistor.

FIG. 4 is a cross-sectional view taken along line 4-4 in FIG. 3.

FIG. 5 is a schematic plan view of an exemplary nitride semiconductor module according to a second embodiment.

FIG. 6 is a schematic circuit diagram of a nitride semiconductor module according to a third embodiment.

FIG. 7 is a schematic plan view of an exemplary nitride semiconductor module according to the third embodiment.

FIG. 8 is a schematic cross-sectional view of a first transistor and a second transistor included in the nitride semiconductor module according to the third embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a semiconductor module according to the present disclosure will be described with reference to the accompanying drawings. For simplicity and clarity of explanation, the components shown in the drawings are not necessarily drawn to a constant scale. Further, in order to facilitate understanding, hatching lines may be omitted in cross-sectional views. The accompanying drawings are merely illustrative of the embodiments of the present disclosure and should not be considered as limiting the present disclosure.

The following detailed description includes apparatuses, systems, and methods that embody exemplary embodiments of the present disclosure. This detailed description is exemplary in nature and is not intended to limit the embodiments of the present disclosure or the application and uses of such embodiments.

### First Embodiment

### [Schematic Structure of Semiconductor Module]

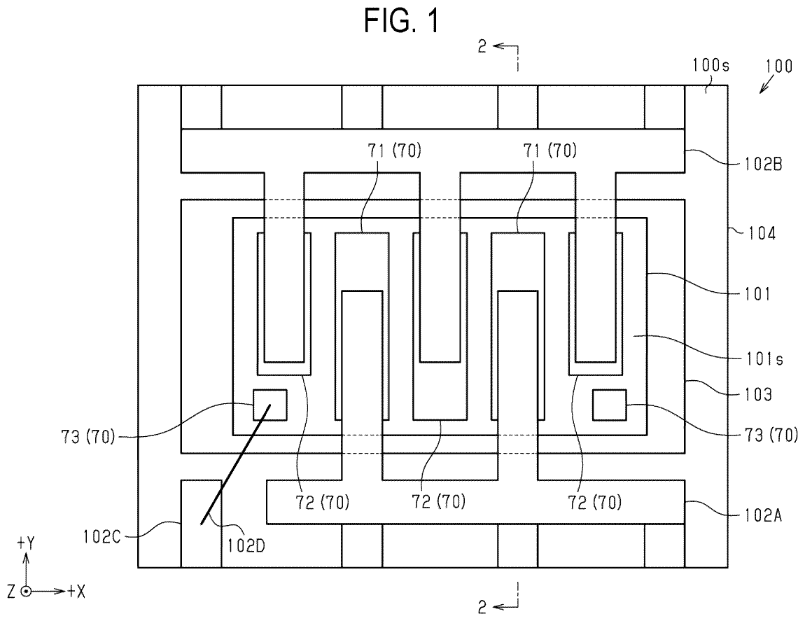

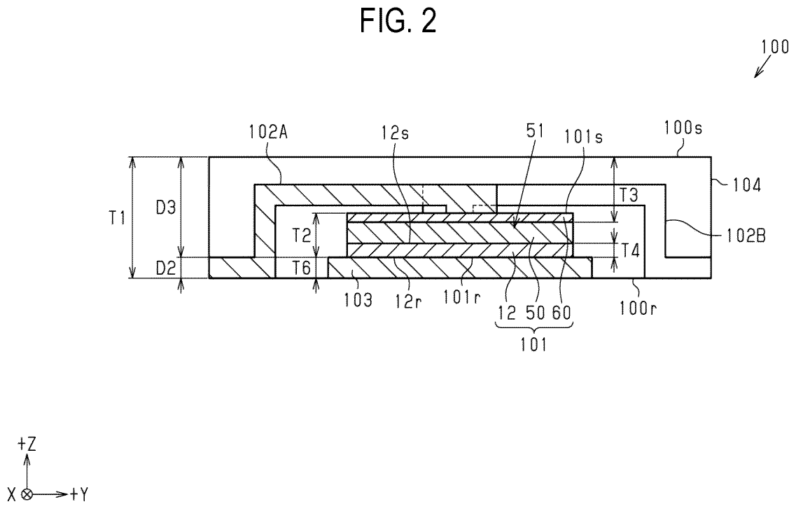

FIG. 1 is a schematic plan view of an exemplary nitride semiconductor module (hereinafter, referred to as a semiconductor module) 100 according to a first embodiment. FIG. 2 is a cross-sectional view taken along line 2-2 in FIG. 1.

As shown in FIGS. 1 and 2, the semiconductor module 100 may be, for example, a surface-mounted package. The semiconductor module 100 includes a module upper surface 100s and a module lower surface 100r facing an opposite side of the module upper surface 100s.

The semiconductor module 100 includes a chip 101 including a transistor 51 to be described later, a first conductive terminal 102A, a second conductive terminal 102B and a third conductive terminal 102C, which are electrically connected to the chip 101, a heat dissipation member 103, and a sealing member 104 that seals the chip 101. In order to facilitate understanding, only an outline of the sealing member 104 is shown in FIGS. 1 and 2.

The chip 101 includes a chip upper surface 101s and a chip lower surface 101r facing an opposite side of the chip upper surface 101s. The chip upper surface 101s is a surface facing a same side as the module upper surface 100s. The chip lower surface 101r is a surface facing a same side as the module lower surface 100r. A shape of the chip 101 in a plan view, i.e., a shape of the chip upper surface 101s and the chip lower surface 101r in a plan view, is, for example, rectangular. The chip 101 includes a semiconductor substrate 12, a nitride semiconductor layer 50, the transistor 51, an insulator layer 60, electrode pads 70, and a lower surface electrode 80. In FIG. 2, the illustration of the electrode pads 70 and the lower surface electrode 80 is omitted.

The semiconductor substrate 12 is a substrate made of GaN. The semiconductor substrate 12 is, for example, a substrate formed of n-type GaN in which N holes function as donors. The carrier density may be, for example, 1×10¹⁶ cm⁻³ or more.

The semiconductor substrate 12 includes a substrate upper surface 12s and a substrate lower surface 12r facing an opposite side of the substrate upper surface 12s. The substrate upper surface 12s is a surface facing a same side as the chip upper surface 101s. The substrate lower surface 12r is a surface facing a same side as the chip lower surface 101r.

A Z-axis direction of mutually orthogonal XYZ axes shown in FIGS. 1 and 2 is a thickness direction of the semiconductor substrate 12. The term “plan view” used in this specification refers to viewing the semiconductor module 100 from above along the Z-axis direction, unless explicitly stated otherwise. Details of a thickness of the semiconductor substrate 12 will be described later.

The nitride semiconductor layer 50 is formed over the substrate upper surface 12s of the semiconductor substrate 12. The transistor 51 is configured by using the nitride semiconductor layer 50. Details of the nitride semiconductor layer 50 and the transistor 51 will be described later.

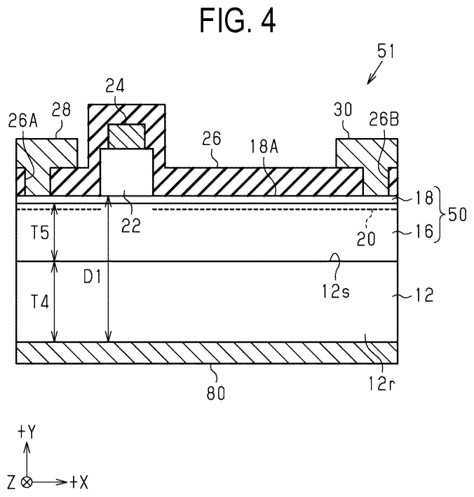

As shown in FIG. 4, the lower surface electrode 80 is formed at the lower surface 12r of the semiconductor substrate 12. The lower surface electrode 80 is electrically connected to a source electrode 28, which will be described later. The lower surface electrode 80 may be made of an arbitrary conductive material containing, for example, at least one selected from the group of titanium (Ti), nickel (Ni), nickel vanadium alloy (NiV), silver (Ag), and gold (Au). The lower surface electrode 80 may include one or more metal layers. For example, an example of the lower surface electrode 80 is an electrode in which three layers of a Ti layer, a Ni layer, and an Au layer are laminated in order from the substrate lower surface 12r of the semiconductor substrate 12. Further, the lower surface electrode 80 may be an electrode formed by stacking four layers of a Ti layer, a Ni layer, an Au layer, and an Ag layer in order from the substrate lower surface 12r of the semiconductor substrate 12, or an electrode formed by stacking three layers of a Ti layer, a NiV layer, and an Ag layer in order from the substrate lower surface 12r of the semiconductor substrate 12. The lower surface electrode 80 constitutes the chip lower surface 101r of the chip 101.

Further, the lower surface electrode 80 may be omitted. In this case, the semiconductor substrate 12 is electrically connected to a source electrode 28, which will be described later. For example, the semiconductor substrate 12 and the source electrode 28 are electrically connected by forming a via in contact with the substrate upper surface 12s of the semiconductor substrate 12 and the source electrode 28 in the nitride semiconductor layer 50 arranged between the semiconductor substrate 12 and the source electrode 28. When the lower surface electrode 80 is omitted, the chip lower surface 101r of the chip 101 may be constituted by, for example, the substrate lower surface 12r of the semiconductor substrate 12.

The insulator layer 60 is formed over the nitride semiconductor layer 50. The insulator layer 60 may be made of, for example, a material containing any one of silicon nitride (SiN), silicon dioxide (SiO2), silicon oxynitride (SiON), alumina (Al₂O₃), AlN, and aluminum oxynitride (AlON). In one example, the insulator layer 60 is formed of a material containing SiN.

The electrode pads 70 are formed over an upper surface of the insulator layer 60. The electrode pads 70 include one or more source pads 71, one or more drain pads 72, and one or more gate pads 73.

In FIG. 2, the illustration of the electrode pads 70 is omitted. The source pad 71 is electrically connected to a source electrode 28, which will be described later. The drain pad 72 is electrically connected to a drain electrode 30, which will be described later. The gate pad 73 is electrically connected to a gate electrode 24, which will be described later. Each of the electrode pads may be made of, for example, an arbitrary conductive material containing at least one selected from the group of Ti, titanium nitride (TiN), aluminum (Al), copper (Cu), AlCu alloy, Ni, and Au. An example of the electrode pad 70 includes a metal layer and a plating layer covering the metal layer. The metal layer has, for example, a structure in which four layers of a Ti layer, a TiN layer, an AlCu layer, and a TiN layer are stacked in order from the upper surface of the insulator layer 60. The plating layer has, for example, a structure in which a Cu layer, a Ni layer, and an Au layer are stacked in this order from the metal layer.

In the example shown in FIG. 2, the chip 101 includes a plurality of source pads 71, a plurality of drain pads 72, and a plurality of gate pads 73. Each of the source pads 71 and each of the drain pads 72 are formed in a rectangular shape extending in a Y-axis direction, and are arranged alternately at intervals in an X-axis direction. The gate pads 73 are arranged at intervals in the Y-axis direction of the pads (drain pads 72 in FIG. 1) arranged on both sides of the X-axis direction among the source pads 71 and the drain pads 72.

A first conductive terminal 102A, a second conductive terminal 102B, and a third conductive terminal 102C are electrically connected to the electrode pads 70 of the chip 101. Specifically, the first conductive terminal 102A is bonded to an upper surface of the source pad 71 via a conductive bonding material (not shown). The second conductive terminal 102B is bonded to an upper surface of the drain pad 72 via a conductive bonding material (not shown). The third conductive terminal 102C is connected to an upper surface of the gate pad 73 via a wire 102D.

The first conductive terminal 102A, the second conductive terminal 102B, and the third conductive terminal 102C are made of, for example, Cu or an alloy containing Cu. A solder or conductive paste may be used as the conductive bonding material. The solder may be a lead (Pb)-free solder such as a tin (Sn)-silver (Ag)-copper (Cu)-based solder, or a lead-containing solder such as a Sn—Pb—Ag-based solder. An example of the conductive paste is an Ag paste. The wire 102D is a bonding wire formed by a wire bonding device, and is made of a conductor such as gold (Au), Al, or Cu.

Each of the first conductive terminal 102A and the second conductive terminal 102B has, for example, a bridge shape. Each of the first conductive terminal 102A, the second conductive terminal 102B, and the third conductive terminal 102C includes an external connection surface (each lower surface) partially exposed from the sealing member 104 to the module lower surface 100r. The external connection surface of each of the first conductive terminal 102A, the second conductive terminal 102B, and the third conductive terminal 102C is electrically connected to a mounting substrate when the semiconductor module 100 is mounted on the mounting substrate (not shown).

The heat dissipation member 103 is installed at the chip lower surface 101r of the chip 101. A method of installing the heat dissipation member 103 at the chip lower surface 101r is not particularly limited. In one example, the heat dissipation member 103 is installed using a bonding material (not shown). Examples of the bonding material include a metal material such as a solder, an Ag paste, or the like, and a resin material such as a thermosetting resin, a photocurable resin, or the like. In another example, the heat dissipation member 103 is bonded to the chip lower surface 101r of the chip 101 by diffusion bonding or solid phase diffusion bonding.

The heat dissipation member 103 includes an exposed surface partially exposed from the sealing member 104 to the module lower surface 100r. The shape of the heat dissipation member 103 is not particularly limited as long as the heat dissipation member 103 includes the exposed surface. The heat dissipation member 103 is, for example, a plate-shaped heat dissipation plate. The heat dissipation member 103 is made of a material with good heat conductivity. The heat dissipation member 103 is made of, for example, ceramics or metal. Ceramics contain, for example, alumina (Al₂O₃) as a main component.

The sealing member 104 may define a package contour of the semiconductor module 100. The sealing member 104 seals a portion of the first conductive terminal 102A, a portion of the second conductive terminal 102B, a portion of the third conductive terminal 102C, and a portion of the heat dissipation member 103, along with the chip 101. The sealing member 104 may be made of an insulating resin material such as an epoxy resin, an acrylic resin, or a phenol resin. In one example, the sealing member 104 may be formed by molding an insulating resin material. The sealing member 104 is made of a material having lower thermal conductivity than the material (GaN) forming the semiconductor substrate 12. The chip upper surface 101s and the chip lower surface 101r of the chip 101 are formed by the sealing member 104.

### [Details of Nitride Semiconductor Layer and Transistor]

### (Schematic Structure of Transistor)

The chip 101 includes an active region where the transistor 51 is formed, and an inactive region where the transistor 51 is not formed in a plan view.

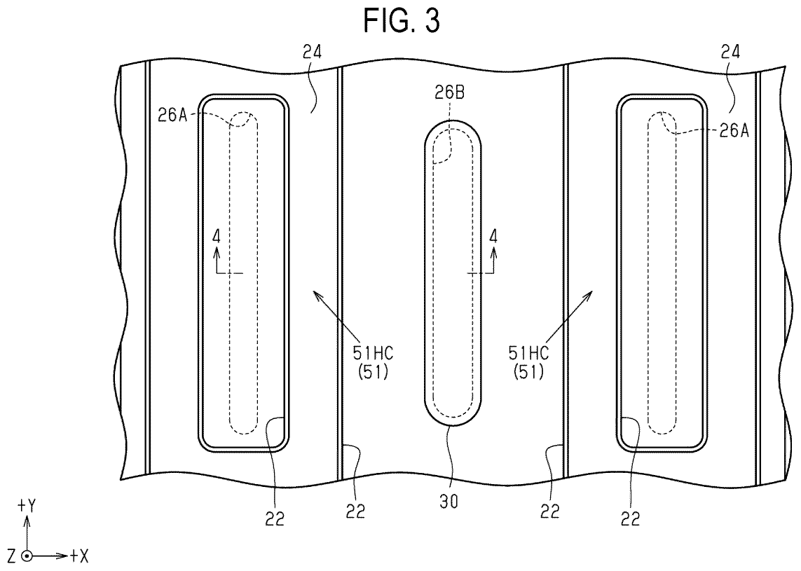

FIG. 3 is a schematic plan view of the transistor 51 formed in an active region. In FIG. 3, the insulator layer 60 and the electrode pads 70 are omitted. FIG. 4 is a schematic cross-sectional view of the transistor 51, and is a cross-sectional view taken along line 4-4 in FIG. 3. In one example, the transistor 51 may be a HEMT using GaN. A cross-sectional structure of the transistor 51 will be described below with reference to FIG. 4, and then a plan-view structure of the transistor 51 will be described with reference to FIG. 3.

As shown in FIG. 4, the transistor 51 includes the semiconductor substrate 12 and the nitride semiconductor layer 50 formed over the semiconductor substrate 12. The nitride semiconductor layer 50 is epitaxially grown on the substrate upper surface 12s of the semiconductor substrate 12. The nitride semiconductor layer 50 includes an electron transit layer 16 formed over the semiconductor substrate 12 and an electron supply layer 18 formed over the electron transit layer 16.

The electron transit layer 16 is a GaN layer made of GaN. An example of the electron transit layer 16 is an undoped GaN layer. Details of a thickness of the electron transit layer 16 will be described later. In order to suppress current leakage in the electron transit layer 16, an impurity may be introduced into a portion of the electron transit layer 16 to make the region other than a surface layer of the electron transit layer 16 semi-insulating. In this case, the impurity is, for example, C, and a peak concentration of the impurity in the electron transit layer 16 is, for example, 1×10¹⁹ cm⁻³ or more.

The electron supply layer 18 is made of a nitride semiconductor having a larger band gap than the electron transit layer 16. The electron supply layer 18 is, for example, an AlGaN layer. In this case, as the Al composition becomes larger, the bandgap becomes larger. Therefore, the electron supply layer 18, which is an AlGaN layer, has a larger bandgap than the electron transit layer 16, which is a GaN layer. In one example, the electron supply layer 18 is made of AlₓGa₁₋ₓN, where x satisfies 0.1<x<0.4, more preferably 0.2<x<0.3. A thickness of the electron supply layer 18 is, for example, 5 nm or more and 20 nm or less.

The electron transit layer 16 and the electron supply layer 18 are composed of nitride semiconductors having different lattice constants. Therefore, the GaN layer constituting the electron transit layer 16, and the GaN layer (e.g., AlGaN layer) constituting the electron supply layer 18 form a lattice-mismatched heterojunction. Due to the spontaneous polarization of the electron transit layer 16 and the electron supply layer 18 and the piezo polarization caused by a stress applied to the electron supply layer 18 near the heterojunction interface, an energy level of a conduction band of the electron transit layer 16 near the heterojunction interface becomes lower than the Fermi level. As a result, a two-dimensional electron gas (2DEG) 20 spreads in the electron transit layer 16 at a position close to the heterojunction interface between the electron transit layer 16 and the electron supply layer 18 (e.g., at a position within a range of several nm from the heterojunction interface).

The nitride semiconductor layer 50 may include layers other than the electron transit layer 16 and the electron supply layer 18. For example, the nitride semiconductor layer 50 may include an intermediate layer disposed between the semiconductor substrate 12 and the electron transit layer 16. An example of the intermediate layer is a buffer layer provided to facilitate epitaxial growth of the electron transit layer 16, and may be made of an arbitrary material that is capable of facilitating the epitaxial growth of the electron transit layer 16. Another example of the intermediate layer is a high resistance layer provided to suppress current leakage in a vertical direction, i.e., current leakage between the semiconductor substrate 12 and the drain electrode 30 described later, and may be made of an arbitrary material that enables epitaxial growth of the electron transit layer 16. The high resistance layer is, for example, a layer with a higher resistance than the electron transit layer 16.

The transistor 51 includes a gate layer 22 formed over the electron supply layer 18, a gate electrode 24 formed over the gate layer 22, and a passivation layer 26. The passivation layer 26 is formed over the electron supply layer 18, the gate layer 22, and the gate electrode 24, and includes a first opening 26A and a second opening 26B. Further, the transistor 51 includes a source electrode 28 in contact with an upper surface 18A of the electron supply layer 18 via the first opening 26A, and a drain electrode 30 in contact with the upper surface 18A of the electron supply layer 18 via the second opening 26B.

The gate layer 22 is located between the first opening 26A and the second opening 26B of the passivation layer 26, and is spaced apart from each of the first opening 26A and the second opening 26B. The gate layer 22 is located closer to the first opening 26A than the second opening 26B. A thickness of the gate layer 22 is, for example, 50 nm or more and 200 nm or less.

The gate layer 22 has a smaller band gap than the electron supply layer 18 and is made of a nitride semiconductor containing an acceptor type impurity. The gate layer 22 may be made of, for example, an arbitrary material having a smaller bandgap than the electron supply layer 18, which is an AlGaN layer. In one example, the gate layer 22 is a GaN layer (p-type GaN layer) doped with an acceptor type impurity.

The acceptor type impurity may include at least one selected from the group of magnesium (Mg), zinc (Zn), and C. An example of the acceptor type impurity is Mg. A maximum concentration of the acceptor type impurity in the gate layer 22 is, for example, 1×10¹⁸ cm⁻³ or more or 1×10¹⁹ cm⁻³ or more. The maximum concentration of the acceptor type impurity in the gate layer 22 is, for example, 1×10²⁰ cm⁻³ or less.

Since the acceptor type impurity is contained in the gate layer 22 as described above, energy levels of the electron transit layer 16 and the electron supply layer 18 are raised. Therefore, in a region directly below the gate layer 22, the energy level of the conduction band of the electron transit layer 16 near the heterojunction interface between the electron transit layer 16 and the electron supply layer 18 is approximately the same as or higher than the Fermi level. Therefore, at the time of zero bias at which no voltage is applied to the gate electrode 24, a 2DEG 20 is not formed in the electron transit layer 16 in the region directly below the gate layer 22. On the other hand, a 2DEG 20 is formed in the electron transit layer 16 in regions other than the region directly below the gate layer 22.

In this manner, the 2DEG 20 disappears in the region directly below the gate layer 22 due to the presence of the gate layer 22 doped with the acceptor type impurity. As a result, a normally-off operation of the transistor is realized. When an appropriate on-voltage is applied to the gate electrode 24, a channel is formed by the 2DEG 20 in the electron transit layer 16 in the region directly below the gate electrode 24, such that a source and a drain are electrically connected.

The gate electrode 24 includes one or more metal layers. The gate electrode 24 is, for example, a titanium nitride (TiN) layer. Alternatively, the gate electrode 24 may include a first metal layer made of a material containing Ti, and a second metal layer stacked on the first metal layer and made of a material containing TiN. The gate electrode 24 may form a Schottky junction with the gate layer 22. The gate electrode 24 may be formed in a region smaller than the gate layer 22 in a plan view. A thickness of the gate electrode 24 is, for example, 50 nm or more and 200 nm or less.

The passivation layer 26 is formed over the electron supply layer 18. It may be said that the passivation layer 26 covers the upper surface 18A of the electron supply layer 18. The passivation layer 26 may be made of, for example, a material containing any one of silicon nitride (SiN), silicon dioxide (SiO₂), silicon oxynitride (SiON), alumina (Al₂O₃), AlN, and aluminum oxynitride (AlON). In one example, the passivation layer 26 is made of a material containing SiN. A portion of the passivation layer 26 that covers the gate layer 22 and the gate electrode 24 is formed along the upper surfaces of the gate layer 22 and the gate electrode 24, and therefore has a non-flat upper surface. The passivation layer 26 has a thickness of, for example, 200 nm or less. Herein, the thickness of the passivation layer 26 may be, for example, the thickness of a portion in contact with the electron supply layer 18 or the thickness of a portion in contact with an upper surface of the gate electrode 24.

The source electrode 28 and the drain electrode 30 are arranged over the upper surface 18A of the electron supply layer 18 with the gate layer 22 located therebetween. On the upper surface 18A of the electron supply layer 18, the gate layer 22, the source electrode 28, and the drain electrode 30 are aligned in the X-axis direction.

The source electrode 28 and the drain electrode 30 may include one or more metal layers. For example, the source electrode 28 and the drain electrode 30 may include a combination of two or more metal layers selected from the group of a Ti layer, a TiN layer, an Al layer, an AlSiCu layer, and an AlCu layer. At least a portion of the source electrode 28 is filled in the first opening 26A and is in ohmic contact with the 2DEG 20 directly below the electron supply layer 18 via the first opening 26A. Similarly, at least a portion of the drain electrode 30 is filled in the second opening 26B and is in ohmic contact with the 2DEG 20 directly below the electron supply layer 18 via the second opening 26B.

As described above, the source electrode 28 is electrically connected to the source pad 71 via the wiring (not shown) formed in the insulator layer 60. The drain electrode 30 is electrically connected to the drain pad 72 via the wiring (not shown) formed in the insulator layer 60. The gate electrode 24 is electrically connected to the gate pad 73 via the wiring (not shown) formed in the insulator layer 60. Further, the insulator layer 60 is formed over the passivation layer 26, the source electrode 28, and the drain electrode 30. It may also be said that the insulator layer 60 covers the passivation layer 26, the source electrode 28, and the drain electrode 30.

### (Plan-View Structure of Transistor)

Next, a plan-view structure of the transistor 51 will be described with reference to FIG. 3. In FIG. 3, the illustration of the passivation layer 26 and the source electrode 28 is omitted, and the first opening 26A and the second opening 26B of the passivation layer 26 are depicted by broken lines.

The transistor 51 includes, within the active region, first active regions that contribute to the transistor operation and second active regions (not shown) that do not contribute to the transistor operation. In one example, the first active regions and the second active regions are alternately disposed in the Y-axis direction.

In the first active region of the transistor 51, the source electrode 28 (see FIG. 4), the gate electrode 24, and the drain electrode 30 are disposed adjacent to each other in the X-axis direction on the electron supply layer 18 (see FIG. 4). A combination of the source electrode 28, the gate electrode 24, and the drain electrode 30, which are adjacent to each other in the X-axis direction, constitutes one HEMT cell 51HC. In the example of FIG. 3, two HEMT cells 51HC are disposed in the X direction in the active region. In reality, more HEMT cells 51HC may be arranged in each active region. The number of HEMT cells 51HC is not particularly limited, and may be one or more. The chip 101 may include a plurality of transistors 51 (HEMT cells 51HC) formed on a same substrate.

### [Details of Thickness of Each Part of Semiconductor Module]

The thickness of each part of the semiconductor module 100 will be described with reference to FIGS. 2 and 4.

As shown in FIG. 2, a thickness T1 of the semiconductor module 100 is, for example, 900 μm or more. The thickness T1 of the semiconductor module 100 is, for example, 1,500 μm or less. A thickness T2 of the chip 101 is, for example, 80 μm or more. The thickness T2 of the chip 101 is, for example, 140 μm or less.

A distance from an upper surface of the nitride semiconductor layer 50 (the upper surface 18A of the electron supply layer 18) to the module upper surface 100s is defined as a thickness T3. The thickness T3 is, for example, 400 μm or more. The thickness T3 is, for example, 550 μm or less.

As shown in FIG. 4, a thickness T4 of the semiconductor substrate 12 of the chip 101 is 100 μm or less. The thickness T4 of the semiconductor substrate 12 may be 80 μm or less. Further, the thickness T4 of the semiconductor substrate 12 is, for example, 60 μm or more.

An example of the thickness T4 of the semiconductor substrate 12 is thinner than the thickness T3, which is the distance from the upper surface of the nitride semiconductor layer 50 (the upper surface 18A of the electron supply layer 18) to the module upper surface 100s. A ratio (T4/T3) of the thickness T4 of the semiconductor substrate 12 to the thickness T3 is, for example, 0.25 or less. Further, a difference (T3−T4) between the thickness T3 and the thickness T4 of the semiconductor substrate 12 is, for example, 480 μm or more.

As shown in FIG. 4, a thickness T5 of the electron transit layer 16 constituting the nitride semiconductor layer 50 is, for example, 1.2 μm or more. The thickness T5 of the electron transit layer 16 is, for example, 6 μm or less. In an example of the nitride semiconductor layer 50, the electron transit layer 16 is formed over the semiconductor substrate 12 made of n-type GaN, and an intermediate layer such as a buffer layer or the like is not interposed between the semiconductor substrate 12 and the electron transit layer 16. In this case, insulation between the 2DEG 20 generated in the electron transit layer 16 and the semiconductor substrate 12 may be secured by forming the electron transit layer 16 thickly, for example, by setting the thickness T5 to be 1,200 μm or more. As a result, it is possible to suppress a leakage current from flowing through the electron transit layer 16 to the semiconductor substrate 12.

A combined thickness of the semiconductor substrate 12 and the nitride semiconductor layer 50, i.e., a distance D1 from the substrate lower surface 12r of the semiconductor substrate 12 to the upper surface 18A of the electron supply layer 18, is, for example, 106 μm or less. Further, the distance D1 is, for example, 61 μm or more.

As shown in FIG. 2, a thickness T6 of the heat dissipation member 103 is, for example, 150 μm or less. The thickness of the heat dissipation member 103 is, for example, 100 μm or more. By reducing the thickness T6 of the heat dissipation member 103 to, for example, 150 μm or less, it is possible to improve the heat dissipation performance of the heat dissipation member 103. The thickness T6 of the heat dissipation member 103 in one example is thicker than the thickness T4 of the semiconductor substrate 12. Further, the thickness T6 of the heat dissipation member 103 in another example is thinner than the thickness T4 of the semiconductor substrate 12.

In a thickness direction of the semiconductor module 100, the chip lower surface 101r of the chip 101 is located closer to the module lower surface 100r than the module upper surface 100s of the semiconductor module 100. In other words, a distance D2 between the chip lower surface 101r and the module lower surface 100r is shorter than a distance D3 between the chip lower surface 101r and the module upper surface 100s.

### [Operation]

Next, the operation of the semiconductor module 100 of the embodiment will be described. The semiconductor module 100 includes the chip 101 including the transistor 51. The chip 101 includes the semiconductor substrate 12 having the substrate upper surface 12s and the substrate lower surface 12r, and the electron transit layer 16 and the electron supply layer 18, which are formed over the substrate upper surface 12s and made of GaN. The transistor 51 includes the electron transit layer 16 and the electron supply layer 18, and includes the gate electrode 24, the source electrode 28, and the drain electrode 30, which are formed over the electron supply layer 18.

In the case of the chip 101 having the above configuration, heat generated from the transistor 51 is dissipated externally via the semiconductor substrate 12. Specifically, the semiconductor module 100 includes the heat dissipation member 103 that is bonded to the substrate lower surface 12r of the semiconductor substrate 12 and exposed at the module lower surface 100r. The heat generated from the transistor 51 is dissipated externally from the module lower surface 100r of the semiconductor module 100 via the semiconductor substrate 12 and the heat dissipation member 103. Therefore, the semiconductor module 100 may be said to be a single-side heat dissipation type module.

Herein, the chip 101 uses, as the semiconductor substrate 12, a GaN substrate, i.e., a substrate made of a same material as the electron transit layer 16 and the electron supply layer 18 formed over the semiconductor substrate 12. Thus, the thickness of the semiconductor substrate 12 may be made thinner than that of the conventional structure using other substrates. Specifically, the thickness of the semiconductor substrate 12 may be reduced to 100 μm or less.

Specifically, when a material constituting the semiconductor substrate 12 and a material constituting the electron transit layer 16 and electron supply layer 18 formed thereon are different materials, the difference in linear expansion coefficients of the two materials generates a stress that tends to warp the chip 101. As a result, the semiconductor substrate needs to have a thickness that is able to retain a strength to withstand the above stress. For example, when using a Si substrate, a thickness of the Si substrate needs to be 200 μm or more.

On the other hand, when the material constituting the semiconductor substrate 12 and the material constituting the electron transit layer 16 formed thereon are both the same type of material (GaN-based material), the difference in linear expansion coefficients of the two materials becomes small or disappears. Therefore, the stress that tends to warp the chip 101 due to the difference in the linear expansion coefficients becomes smaller or no longer occurs. This makes it possible to reduce the strength required for the semiconductor substrate 12. As a result, it becomes possible to use a semiconductor substrate 12 with relatively low strength, i.e., a semiconductor substrate 12 with a thickness of 100 μm or less.

By using the thin semiconductor substrate 12 with a thickness of 100 μm or less, thermal resistance when heat flows in the thickness direction of the semiconductor substrate 12 may be reduced. As a result, in the chip 101, thermal resistance when the heat generated from the transistor 51 is dissipated externally via the semiconductor substrate 12 is reduced. Thus, heat dissipation of the semiconductor module 100 is improved.

Further, the thermal conductivity of Si used in the conventional semiconductor substrate is 1.5 W/cm·K. On the other hand, the thermal conductivity of GaN is 2 W/cm·K, which is higher than that of Si. Therefore, as compared to a case when a Si substrate is used, when a GaN substrate is used, the effect of improving heat dissipation may be obtained due to the higher thermal conductivity of the material constituting the semiconductor substrate 12.

For reference, thermal resistance of the chip 101 using a GaN substrate as the semiconductor substrate 12 and thermal resistance of the chip 101 using a Si substrate as the semiconductor substrate 12 are compared by simulation. The thermal resistance is determined by determining thermal resistance between a specific first point on the upper surface 18A of the electron supply layer 18 and a specific second point on the substrate lower surface 12r of the semiconductor substrate 12. First, a first model of a semiconductor module including a chip 101 using a Si substrate with a thickness of 200 μm and having an area of 10 mm² in a plan view is prepared, and the thermal resistance thereof is calculated. Next, a second model having the same configuration as the first model except that a GaN substrate with a thickness of 80 μm is used is prepared, and the thermal resistance thereof is calculated. As a result, the thermal resistance of the first model using the Si substrate is calculated to be 0.13 degrees C./W. On the other hand, the thermal resistance of the second model using the GaN substrate is calculated to be 0.04 degrees C./W, which was equal to or less than ⅓ of the thermal resistance of the first model.

### [Effect]

According to the semiconductor module 100 of the first embodiment, the following effects are obtained.
(1-1)

The semiconductor module 100 includes the chip 101 including the transistor 51. The chip 101 includes the semiconductor substrate 12, the electron transit layer 16 formed over the semiconductor substrate 12 and made of GaN, and the electron supply layer 18 formed over the electron transit layer 16 and made of GaN. The transistor 51 includes the gate electrode 24, the source electrode 28, and the drain electrode 30, which are formed over the electron supply layer 18. The semiconductor substrate 12 is a GaN substrate having a thickness of 100 μm or less.

According to the above configuration, by using the GaN substrate as the semiconductor substrate 12, the thickness of the semiconductor substrate 12 may be set to 100 μm or less. This reduces the thermal resistance when the heat generated from the transistor 51 is dissipated externally via the semiconductor substrate 12. As a result, the heat dissipation of the semiconductor module 100 is improved. By improving the heat dissipation of the semiconductor module 100, an amount of heat generated by the chip 101 is reduced. This makes it possible to increase an upper limit of the drain current (allowable current) that flows through the transistor 51.
(1-2)

Further, when the semiconductor substrate 12 is the GaN substrate, the electron transit layer 16 and the electron supply layer 18, which are GaN layers, may be formed over the semiconductor substrate 12 by epitaxial growth without using a buffer layer. For example, the electron supply layer 18 is formed in contact with the substrate upper surface 12s of the semiconductor substrate 12.

In this case, by omitting a buffer layer, it is possible to shorten a distance from the upper surface 18A of the electron supply layer 18 to the semiconductor substrate 12. This makes it possible to shorten a heat dissipation path through which the heat generated from the transistor 51 is dissipated externally via the electron transit layer 16 and the semiconductor substrate 12. In this respect as well, the thermal resistance when the heat generated from the transistor 51 is dissipated externally through the heat dissipation path is reduced. As a result, the heat dissipation of the semiconductor module 100 is further improved.

Further, when the electron transit layer 16 is disposed over the semiconductor substrate 12 made of n-type GaN without using a buffer layer, the electron transit layer 16 made of undoped GaN may be formed thick to ensure insulation between the 2DEG 20 and the semiconductor substrate 12. In this case as well, a decrease in the thickness of the electron transit layer 16 due to the omission of the buffer layer is greater than an increase in the thickness of the electron transit layer 16. Therefore, the distance from the upper surface 18A of the electron supply layer 18 to the semiconductor substrate 12 may be made shorter than that of the configuration having a buffer layer.
(1-3)

The chip 101 includes the plurality of transistors 51 (HEMT cells 51HC). Each of the transistors 51 is a horizontal transistor in which the gate electrode 24, the source electrode 28, and the drain electrode 30 are formed over the electron supply layer 18. The chip 101 may be miniaturized by arranging the plurality of transistors 51, which are horizontal transistors, in a dense manner. However, the amount of heat generated by the chip 101 tends to increase as the heat generated from each of the adjacent transistors 51 interferes with each other. Therefore, it is particularly effective to use a GaN substrate having a thickness of 100 μm or less for the chip 101 including the plurality of transistors 51.
(1-4)

The semiconductor module 100 includes the sealing member 104 that covers the chip 101. The semiconductor module 100 includes the module upper surface 100s facing a same side as the substrate upper surface 12s, and the module lower surface 100r facing a same side as the substrate lower surface 12r. The thickness T4 of the semiconductor substrate 12 is thinner than the thickness T3, which is the distance from the upper surface 18A of the electron supply layer 18 to the module upper surface 100s. In this case, since the thickness T4 of the semiconductor substrate 12 is thin, the thermal resistance when the heat generated from the transistor 51, especially near the electron supply layer 18, is dissipated externally via the semiconductor substrate 12, is further reduced.
(1-5)

In the thickness direction of the semiconductor substrate 12, the chip lower surface 101r of the chip 101 is located closer to the module lower surface 100r than the module upper surface 100s of the semiconductor module 100. In this case, it is possible to shorten the one-sided heat dissipation path through which the heat generated from the transistor 51 is dissipated from the module lower surface 100r via the semiconductor substrate 12. Thus, the thermal resistance when the heat generated from the transistor 51 is dissipated externally via the semiconductor substrate 12 is further reduced.
(1-6)

The transistor 51 is formed over the electron supply layer 18 and includes the gate layer 22 made of GaN containing an acceptor type impurity. The gate electrode 24 is formed over the gate layer 22. That is, the transistor 51 is of a normally-off type. In this case, at a zero bias at which no voltage is applied to the gate electrode 24, no 2DEG 20 is formed in the region directly below the gate layer 22 in the electron transit layer 16. On the other hand, a 2DEG 20 is formed in the electron transit layer 16 in the regions other than the region directly below the gate layer 22. When an on-voltage is applied to the gate electrode 24, a channel is formed by the 2DEG 20 in the electron transit layer 16 in the region directly below the gate electrode 24.

Herein, when the on-voltage is applied to the gate electrode 24, the 2DEG 20 generated in the region directly below the gate layer 22 in the electron transit layer 16 is less than the 2DEG 20 generated in the regions other than the region directly below the gate layer 22 in the electron transit layer 16. Therefore, the region directly below the gate layer 22 in the electron transit layer 16 has a higher resistance than the regions other than the region directly below the gate layer 22 in the electron transit layer 16, resulting in an increase in an amount of heat generated. Therefore, when the transistor 51 included in the chip 101 is a normally-off type transistor having the gate layer 22, the amount of heat generated by the chip 101 tends to become larger than when the transistor 51 is a normally-on type transistor having no gate layer 22. Thus, it is particularly effective to use a GaN substrate having a thickness of 100 μm or less for the chip 101 including the normally-off type transistor 51.

### Second Embodiment

A semiconductor module 200 of a second embodiment differs from that of the first embodiment in that it includes a control circuit. The other configurations are the same as those in the first embodiment. Hereinafter, the components similar to those of the first embodiment will not be described, and the components different from those of the first embodiment will be described.

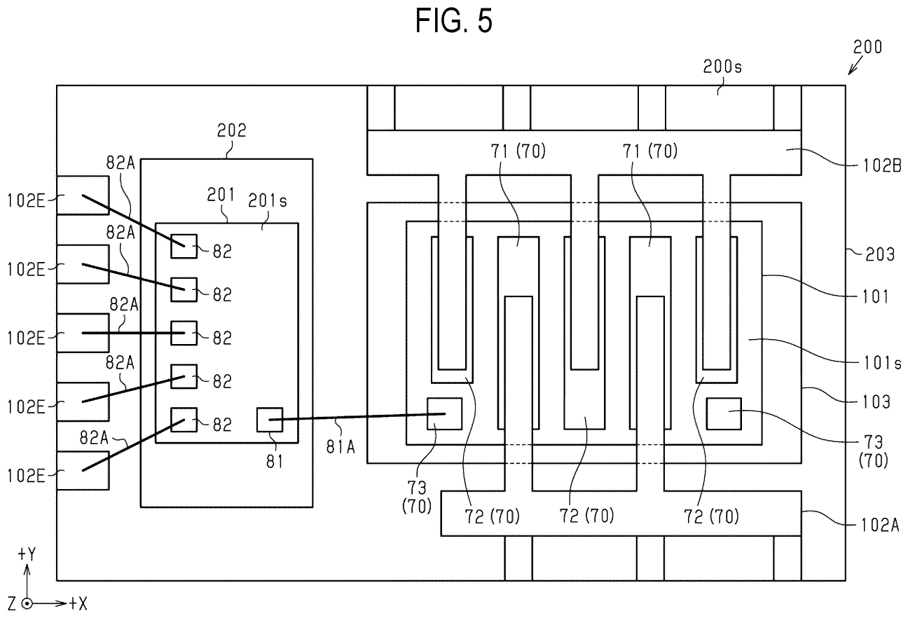

FIG. 5 is a schematic plan view of an exemplary semiconductor module 200 according to the second embodiment.

### [Schematic Structure of Semiconductor Module]

As shown in FIG. 5, the semiconductor module 200 includes a module upper surface 200s and a module lower surface (not shown) facing an opposite side of the module upper surface 200s.

The semiconductor module 200 includes a chip 101 including a transistor 51, a first conductive terminal 102A and a second conductive terminal 102B electrically connected to the chip 101, and a heat dissipation member 103. These components are the same as those of the first embodiment.

The semiconductor module 200 further includes a control chip 201 including a control circuit, a plurality of fourth conductive terminals 102E electrically connected to the control chip 201, a control heat dissipation member 202, and a sealing member 203 that seals the chip 101 and the control chip 201.

The fourth conductive terminal 102E includes an external connection surface (each lower surface) partially exposed from the sealing member 203 to the module lower surface. A material forming the fourth conductive terminal 102E may be the same as a material forming the first conductive terminal 102A.

The control chip 201 includes a chip upper surface 201s facing a same side as the module upper surface 200s. The control chip 201 includes a first electrode pad 81 and a plurality of second electrode pads 82 formed over the chip upper surface 201s. The first electrode pad 81 is connected to an upper surface of the gate pad 73 of the chip 101 via a wire 81A. The plurality of second electrode pads 82 are respectively connected to different fourth conductive terminals 102E via wires 82A. Materials forming the first electrode pad 81 and the second electrode pads 82 may be the same as a material forming the electrode pad 70. Materials forming the wires 81A and 82A may be the same as a material forming the wire 102D.

The control heat dissipation member 202 is installed at a chip lower surface of the control chip 201. The method of installing the control heat dissipation member 202 at the chip lower surface is not particularly limited. The method for installing the control heat dissipation member 202 may be the same as the method described above for the heat dissipation member 103. The control heat dissipation member 202 includes an exposed surface (not shown) that is partially exposed from the sealing member 203 to the module lower surface. A material forming the control heat dissipation member 202 may be the same as a material forming the heat dissipation member 103.

The sealing member 203 may define a package contour of the semiconductor module 200. The sealing member 203 seals a portion of the first conductive terminal 102A, a portion of the second conductive terminal 102B, a portion of the fourth conductive terminals 102E, a portion of the heat dissipation member 103, and a portion of the control heat dissipation member 202, along with the chip 101 and the control chip 201. A material forming the sealing member 203 may be the same as a material forming the sealing member 104.

The control circuit of the control chip 201 generates a drive signal that drives the transistor 51. The drive signal is applied to the gate electrode 24 of the transistor 51. The control circuit turns the transistor 51 on and off.

### [Effect]

The semiconductor module 200 of the second embodiment has the same effects as the semiconductor module 100 of the first embodiment.

### Third Embodiment

A semiconductor module 300 of a third embodiment differs from that of the second embodiment in that it is embodied as a bridge module having a bridge circuit. In the present embodiment, as an example, a semiconductor module 300 embodied as a half-bridge module having a half-bridge circuit will be described.

### [Circuit Configuration of Semiconductor Module]

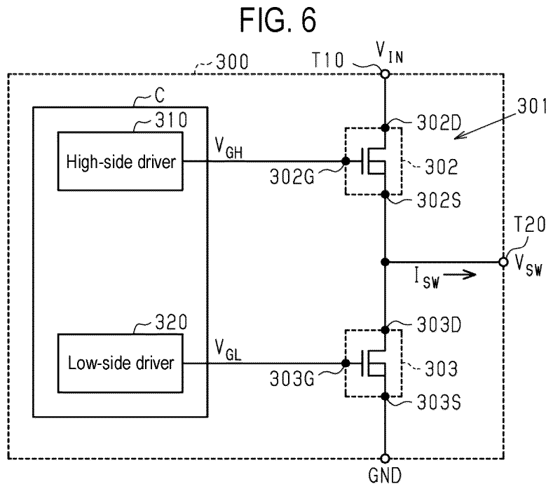

FIG. 6 is a schematic circuit diagram of the semiconductor module 300. The semiconductor module 300 includes a half-bridge circuit 301 and a control circuit C. The half-bridge circuit 301 includes a first transistor 302 and a second transistor 303. The control circuit C controls the driving of the first transistor 302 and the second transistor 303.

The first transistor 302 and the second transistor 303 are connected in series with each other. The first transistor 302 functions as a high-side transistor (control transistor) of the half-bridge circuit 301, and the second transistor 303 functions as a low-side transistor (synchronous rectification transistor) of the half-bridge circuit 301.

The first transistor 302 provided as the high-side transistor includes a source terminal 302S, a drain terminal 302D, and a gate terminal 302G. The drain terminal 302D is connected to an input terminal T10, and the source terminal 302S is connected to an output terminal T20. An input voltage V_{IN} is applied to the input terminal T10.

The second transistor 303 provided as the low-side transistor includes a source terminal 303S, a drain terminal 303D, and a gate terminal 303G. The drain terminal 303D is connected to the output terminal T20, and the source terminal 303S is connected to a ground GND. Therefore, the first transistor 302 and the second transistor 303 are connected in series between the input terminal T10 and the ground GND, and a connection node between the first transistor 302 and the second transistor 303 is connected to the output terminal T20.

The control circuit C includes a high-side driver 310 and a low-side driver 320. The high-side driver 310 generates a high-side control signal V_{GH} that drives the first transistor 302. The high-side control signal V_{GH} is applied to the gate terminal 302G of the first transistor 302. The low-side driver 320 generates a low-side control signal V_{GL} that drives the second transistor 303. The low-side control signal V_{GL} is applied to the gate terminal 303G of the second transistor 303.

The control circuit C generates a switch voltage V_{SW} at the output terminal T20 by performing complementary on/off control of the first transistor 302 and the second transistor 303 based on the high-side control signal V_{GH} and the low-side control signal V_{GL}. A load circuit (not shown) including, for example, a coil and an inductor is connected to the output terminal T20.

When the first transistor 302 is turned on and the second transistor 303 is turned off, a switch current I_{SW} flows from the input terminal T10 to the load circuit (output terminal T20) via the first transistor 302, and a switch voltage V_{SW} based on the input voltage V_{IN} is outputted to the output terminal T20. When the first transistor 302 is turned off and the second transistor 303 is turned on, the switch current I_{SW} flows from the load circuit (output terminal T20) to the ground GND via the second transistor 303, and the switch voltage V_{SW} is lowered to 0 V.

### [Schematic Structure of Semiconductor Module]

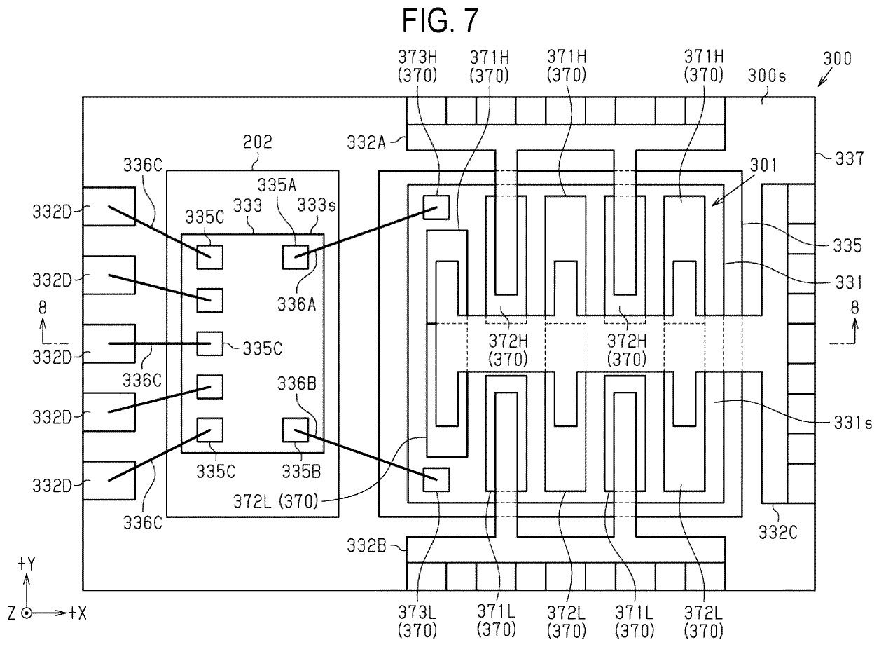

As shown in FIG. 7, the semiconductor module 300 includes a module upper surface 300s and a module lower surface (not shown) facing an opposite side of the module upper surface 300s.

The semiconductor module 300 includes a chip 331 including the first transistor 302 and the second transistor 303, a fifth conductive terminal 332A, a sixth conductive terminal 332B and a seventh conductive terminal 332C, which are electrically connected to the chip 331, and a heat dissipation member 335 bonded to the chip 331. The semiconductor module 300 further includes a control chip 333 including a control circuit C, a plurality of eighth conductive terminals 332D electrically connected to the control chip 333, a control heat dissipation member 202, and a sealing member 337 that seals the chip 331 and the control chip 333. For ease of understanding, only the contour of the sealing member 337 is shown in FIG. 7.

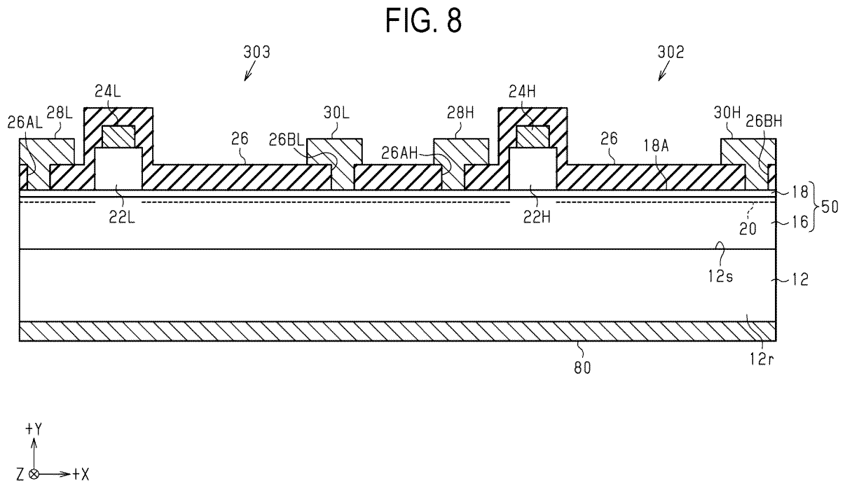

The chip 331 includes a chip upper surface 331s facing a same side as the module upper surface 300s. A shape of the chip 331 in a plan view, i.e., a shape of the chip upper surface 331s in a plan view, is, for example, rectangular. The chip 331 includes a semiconductor substrate 12, a nitride semiconductor layer 50 (see FIG. 8), a first transistor 302 (see FIG. 8), a second transistor 303 (see FIG. 8), an insulator layer 60 (not shown), an electrode pad 370, and a lower surface electrode 80. The semiconductor substrate 12, the lower surface electrode 80 (see FIG. 8), and the insulator layer 60 are the same as those in the first embodiment. Details of the nitride semiconductor layer 50 will be described later.

The electrode pad 370 is formed over the chip upper surface 331s. The electrode pad 370 includes one or more source pads 371H, one or more drain pads 372H, and one or more gate pads 373H. The source pad 371H is electrically connected to a source electrode 28H of the first transistor 302, which will be described later. The drain pad 372H is electrically connected to a drain electrode 30H of the first transistor 302, which will be described later. The gate pad 373H is electrically connected to a gate electrode 24H of the first transistor 302, which will be described later.

Further, the electrode pad 370 includes one or more source pads 371L, one or more drain pads 372L, and one or more gate pads 373L. The source pad 371L is electrically connected to a source electrode 28L of the second transistor 303, which will be described later. The drain pad 372L is electrically connected to a drain electrode 30L of the second transistor 303, which will be described later. The gate pad 373L is electrically connected to a gate electrode 24L of the second transistor 303, which will be described later. A material forming the electrode pad 370 is the same as a material forming the electrode pad 70 of the first embodiment.

In the example shown in FIG. 7, the chip 331 includes a plurality of source pads 371H, a plurality of drain pads 372H, a gate pad 373H, a plurality of source pads 371L, a plurality of drain pads 372L, and a gate pad 373L.

The plurality of source pads 371H and the plurality of drain pads 372H are each formed in a rectangular shape extending in the Y-axis direction, and are arranged alternately in the X-axis direction in a region along a +Y-axis direction of the chip upper surface 331s. The gate pad 373H is arranged closer to an outer periphery of the chip upper surface 331s than the plurality of source pads 371H and the plurality of drain pads 372H. More specifically, the gate pad 373H is arranged at an interval in the +Y-axis direction from a pad (source pad 371H in FIG. 7) arranged at an end in a −X-axis direction.

The plurality of source pads 371L and the plurality of drain pads 372L are each formed in a rectangular shape extending in the Y-axis direction, and are arranged alternately at intervals in the X-axis direction in a region along a −Y-axis direction of the chip upper surface 331s. Further, the source pads 371L are arranged at intervals toward the −Y-axis direction of the drain pad 372H. The drain pads 372L are arranged at intervals toward the −Y-axis direction of the source pad 371H. The gate pad 373L is arranged closer to the outer periphery of the chip upper surface 331s than the plurality of source pads 371L and the plurality of drain pads 372L. Specifically, the gate pad 373L is arranged at an interval in the −Y-axis direction from a pad (drain pad 372L in FIG. 7) arranged at the end in the −X-axis direction.

The fifth conductive terminal 332A, the sixth conductive terminal 332B, and the seventh conductive terminal 332C are electrically connected to the electrode pad 370 of the chip 331. Specifically, the fifth conductive terminal 332A is bonded to an upper surface of the drain pad 372H via a conductive bonding material (not shown). The sixth conductive terminal 332B is bonded to an upper surface of the source pad 371L via a conductive bonding material (not shown). The seventh conductive terminal 332C is bonded to both an upper surface of the source pad 371H and an upper surface of the drain pad 372L via a conductive bonding material (not shown).

Each of the fifth conductive terminal 332A, the sixth conductive terminal 332B, and the seventh conductive terminal 332C has a bridge shape, for example. Each of the fifth conductive terminal 332A, the sixth conductive terminal 332B, and the seventh conductive terminal 332C includes an external connection surface (lower surface of each terminal) that is partially exposed from the sealing member 337 to the module lower surface. The external connection surface of the fifth conductive terminal 332A corresponds to the input terminal T10 in FIG. 6. The external connection surface of the sixth conductive terminal 332B corresponds to the ground GND in FIG. 6. The external connection surface of the seventh conductive terminal 332C corresponds to the output terminal T20 in FIG. 6.

The control chip 333 includes a chip upper surface 333s facing a same side as the module upper surface 300s. A shape of the control chip 333 in a plan view, i.e., a shape of the chip upper surface 333s in a plan view, is, for example, rectangular.

The control chip 333 includes a third electrode pad 335A, a fourth electrode pad 335B, and a plurality of fifth electrode pads 335C, which are formed over the chip upper surface 333s. The third electrode pad 335A is connected to an upper surface of the gate pad 373H of the chip 331 via a wire 336A. The fourth electrode pad 335B is connected to an upper surface of the gate pad 373L of the chip 331 via a wire 336B. The fifth electrode pads 335C are respectively connected to a plurality of different eighth conductive terminals 332D via wires 336C. Each of the plurality of eighth conductive terminals 332D has an external connection surface (lower surface of each terminal) partially exposed from the sealing member 337 to the module lower surface.

### (Schematic Structure of First Transistor and Second Transistor)

FIG. 8 is a schematic cross-sectional view of the first transistor 302 and the second transistor 303. The first transistor 302 and the second transistor 303 include a common semiconductor substrate 12 and a common nitride semiconductor layer 50 formed over the semiconductor substrate 12. The nitride semiconductor layer 50 is epitaxially grown over the substrate upper surface 12s of the semiconductor substrate 12. The nitride semiconductor layer 50 includes an electron transit layer 16 formed over the semiconductor substrate 12 and an electron supply layer 18 formed over the electron transit layer 16. The semiconductor substrate 12 and the nitride semiconductor layer 50 are the same as those of the first embodiment.

The first transistor 302 includes a gate layer 22H formed over the electron supply layer 18 and a gate electrode 24H formed over the gate layer 22H. The second transistor 303 includes a gate layer 22L formed over the electron supply layer 18 and a gate electrode 24L formed over the gate layer 22L.

The first transistor 302 and the second transistor 303 include a passivation layer 26. The passivation layer 26 is formed over the electron supply layer 18, the gate layers 22H and 22L, and the gate electrodes 24H and 24L, and includes first openings 26AH and 26AL and second openings 26BH and 26BL.

The first openings 26AH and 26AL and the second openings 26BH and 26BL are arranged at intervals in the order of the first opening 26AL, the second opening 26BL, the first opening 26AH, and the second opening 26BH toward a +X direction. In one example, in the X direction, a distance between the first opening 26AL and the second opening 26BL is equal to a distance between the first opening 26AH and the second opening 26BH. A distance between the second opening 26BL and the first opening 26AH is shorter than the distance between the first opening 26AL and the second opening 26BL and the distance between the first opening 26AH and the second opening 26BH.

The first transistor 302 includes the source electrode 28H in contact with the upper surface 18A of the electron supply layer 18 via the first opening 26AH, and the drain electrode 30H in contact with the upper surface 18A of the electron supply layer 18 via the second opening 26BH. The gate layer 22H of the first transistor 302 is located between the first opening 26AH and the second opening 26BH of the passivation layer 26, and is spaced apart from each of the first opening 26AH and the second opening 26BH. The source electrode 28H and the drain electrode 30H are disposed over the upper surface 18A of the electron supply layer 18 with the gate layer 22H located therebetween. On the upper surface 18A of the electron supply layer 18, the gate layer 22H, the source electrode 28H, and the drain electrode 30H are arranged in the X-axis direction. The details of the configuration of the first transistor 302 are the same as those of the transistor 51 of the first embodiment. The source electrode 28H is electrically connected to the source pad 371H. The drain electrode 30H is electrically connected to the drain pad 372H. The gate electrode 24H is electrically connected to the gate pad 373H.

The second transistor 303 includes the source electrode 28L in contact with the upper surface 18A of the electron supply layer 18 via the first opening 26AL, and the drain electrode 30L in contact with the upper surface 18A of the electron supply layer 18 via the second opening 26BL. The gate layer 22L of the second transistor 303 is located between the first opening 26AL and the second opening 26BL of the passivation layer 26, and is spaced apart from each of the first opening 26AL and the second opening 26BL. The source electrode 28L and the drain electrode 30L are disposed over the upper surface 18A of the electron supply layer 18 with the gate layer 22L located therebetween. On the upper surface 18A of the electron supply layer 18, the gate layer 22L, the source electrode 28L, and the drain electrode 30L are arranged in the X-axis direction. The source electrode 28L is electrically connected to the source pad 371L. The drain electrode 30L is electrically connected to the drain pad 372L. The gate electrode 24L is electrically connected to the gate pad 373L.

### [Effect]

The semiconductor module 300 of the third embodiment has the same effects as the semiconductor module 100 of the first embodiment. Further, according to the semiconductor module 300 of the third embodiment, the following effects may be obtained.

(3-1)

The chip 331 includes the bridge circuit configured by the plurality of transistors (first transistor 302 and second transistor 303). An example of the bridge circuit is the half-bridge circuit 301 including the first transistor 302 (high-side transistor) and the second transistor 303 (low-side transistor) connected in series. The semiconductor module 300 includes the control circuit C that controls on/off of the plurality of transistors (first transistor 302 and second transistor 303).

In the case of the bridge circuit, the plurality of transistors are disposed close to each other in order to operate at a high frequency and to reduce the size of the chip 331. Therefore, an amount of heat generated by the chip 331 tends to increase as heat generated from the adjacent transistors interferes with each other. Therefore, it is particularly effective to use a GaN substrate having a thickness of 100 μm or less for the chip 101 including the bridge circuit.

### Modification

Each of the above-described embodiments may be modified as follows, for example. The above-described embodiments and the following modifications may be combined with each other as long as there is no technical contradiction. In addition, in the following modifications, parts common to the above-described embodiments are designated by the same reference numerals as in each of the above-described embodiments, and the description thereof will be omitted.

The transistor 51 may be of a normally-on type that does not have the gate layer 22. The same applies to the first transistor 302 and the second transistor 303.

As used herein, the term “over” includes the meanings of both “on” and “above” unless the context clearly indicates otherwise. Thus, the phrase “a first layer is formed over a second layer” refers to a case where the first layer is directly disposed on the second layer in contact with the second layer in a certain embodiment and a case where the first layer is arranged above the second layer without contacting the second layer in another embodiment. That is, the term “over” does not exclude a structure in which another layer is formed between the first layer and the second layer.

The term Z direction used herein does not necessarily have to be the vertical direction, nor does it have to completely coincide with the vertical direction. Therefore, various structures according to the present disclosure are not limited to structures in which the “up” and “down” in the Z direction described herein are “up” and “down” in the vertical direction. For example, the X-axis direction may be a vertical direction, or the Y-axis direction may be a vertical direction.

The terms such as “first,” “second,” and “third” in the present disclosure are used merely to distinguish between objects, and are not intended to rank the objects.

### <Supplementary Notes>

The technical ideas that may be understood from the present disclosure are described below. Not for the purpose of limitation but for the purpose of aiding understanding, the reference numerals of the corresponding components in the embodiments are attached to the components recited in the supplementary notes. The reference numerals are indicated by way of example to aid understanding, and the components recited in each supplementary note should not be limited to the components indicated by the reference numerals.

[Supplementary Note 1] A nitride semiconductor module (100, 200 or 300), including:
a chip (101 or 331) including at least one transistor (51, 302 or 303),
wherein the chip (101 or 331) includes:
   a semiconductor substrate (12) including a substrate upper surface (12s) and a substrate lower surface (12r) facing an opposite side of the substrate upper surface (12s);
   an electron transit layer (16) formed over the substrate upper surface (12s) of the semiconductor substrate (12) and made of GaN; and
   an electron supply layer (18) formed over the electron transit layer (16) and made of GaN having a larger band gap than the electron transit layer (16),
wherein the at least one transistor (51, 302 or 303) includes a gate electrode (24), a source electrode (28), and a drain electrode (30), which are formed over the electron supply layer (18), and
wherein the semiconductor substrate (12) is a GaN substrate having a thickness of 100 μm or less.

[Supplementary Note 2] The nitride semiconductor module of Supplementary Note 1, wherein the at least one transistor (51, 302 or 303) includes a plurality of transistors (51, 302 and 303), and
wherein the chip (101 or 331) includes the plurality of transistors (51, 302 and 303).

[Supplementary Note 3] The nitride semiconductor module of Supplementary Note 1 or 2, further including:
a sealing member (26 or 203) configured to cover the chip (101 or 331),
wherein the nitride semiconductor module includes a module upper surface (100s, 200s or 300s) formed of the sealing member (26 or 203) and facing a same side as the substrate upper surface (12s), and a module lower surface (100r, 200r or 300r) formed of the sealing member (26 or 203) and facing a same side as the substrate lower surface (12r), and
wherein a thickness (T4) of the semiconductor substrate (12) is thinner than a distance (T3) from an upper surface (18A) of the electron supply layer (18) to the module upper surface (100s, 200s or 300s).

[Supplementary Note 4] The nitride semiconductor module (100, 200 or 300) of any one of Supplementary Notes 1 to 3, further including:
a sealing member (26 or 203) configured to cover the chip (101 or 331),
wherein the nitride semiconductor module includes a module upper surface (100s, 200s or 300s) formed of the sealing member (26 or 203) and facing a same side as the substrate upper surface (12s), and a module lower surface (100r, 200r or 300r) formed of the sealing member (26 or 203) and facing a same side as the substrate lower surface (12r), and
wherein a chip lower surface (101r or 331r) of the chip (101 or 331) is located closer to the module lower surface (100r, 200r or 300r) than the module upper surface (100s, 200s or 300s) in a thickness direction of the semiconductor substrate (12).

[Supplementary Note 5] The nitride semiconductor module (100, 200 or 300) of any one of Supplementary Notes 1 to 4, further including:
a sealing member (26 or 203) configured to cover the chip (101 or 331),
wherein the nitride semiconductor module includes a module upper surface (100s, 200s or 300s) formed of the sealing member (26 or 203) and facing a same side as the substrate upper surface (12s), and a module lower surface (100r, 200r or 300r) formed of the sealing member (26 or 203) and facing a same side as the substrate lower surface (12r), and
wherein the nitride semiconductor module further includes a heat dissipation member (103) installed at the substrate lower surface (12r) and exposed to the module lower surface (100r, 200r or 300r).

[Supplementary Note 6] The nitride semiconductor module (100, 200 or 300) of Supplementary Note 5, wherein the heat dissipation member (103) has a thickness of 150 μm or less.

[Supplementary Note 7] The nitride semiconductor module of any one of Supplementary Notes 1 to 6, wherein the electron transit layer (16) is a GaN layer, and
wherein the electron supply layer (18) is an AlGaN layer.

[Supplementary Note 8] The nitride semiconductor module (100, 200 or 300) of any one of Supplementary Notes 1 to 7, wherein the at least one transistor (51, 302 or 303) includes a gate layer (22) formed over the electron supply layer (18) and made of GaN containing an acceptor type impurity, and
wherein the gate electrode (24) is formed over the gate layer (22).

[Supplementary Note 9] The nitride semiconductor module (100, 200 or 300) of Supplementary Note 8, wherein the electron transit layer (16) is a GaN layer,
wherein the electron supply layer (18) is an AlGaN layer, and
wherein the gate layer (22) is a GaN layer containing the acceptor type impurity.

[Supplementary Note 10] The nitride semiconductor module (200 or 300) of any one of Supplementary Notes 1 to 9, further including:
a control circuit (C1 or C2) configured to control an on/off operation of the at least one transistor (51, 302 or 303).

[Supplementary Note 11] The nitride semiconductor module (300) of any one of Supplementary Notes 1 to 9, wherein the at least one transistor (51, 302 or 303) includes a plurality of transistors (51, 302 and 303), and
wherein the chip (101 or 331) includes the plurality of transistors (51, 302 and 303), and
wherein the nitride semiconductor module (300) further includes a bridge circuit (301) configured by using the plurality of transistors (302 and 303).

[Supplementary Note 12] The nitride semiconductor module (300) of Supplementary Note 11, wherein the plurality of transistors (302 and 303) constitutes a half-bridge circuit (301) including a high-side transistor (302) and a low-side transistor (303) connected in series with each other, and
wherein the nitride semiconductor module (300) further includes a control circuit (C2) configured to control on/off operations of the high-side transistor (302) and the low-side transistor (303).

[Supplementary Note 13] A chip including:
a nitride semiconductor layer (50) formed over a semiconductor substrate (12); and
a plurality of transistors (302 and 303) including the nitride semiconductor layer (50),
wherein the plurality of transistors (302 and 303) constitutes a half-bridge circuit (301) including a high-side transistor (302) and a low-side transistor (303) connected in series with each other,
wherein the chip further includes: one or more source pads (371H) formed over a chip upper surface (101s) orthogonal to a thickness direction of the semiconductor substrate (12) and electrically connected to a source electrode (28H) of the high-side transistor (302); one or more drain pads (372H) formed over the chip upper surface (101s) and electrically connected to a drain electrode (30H) of the high-side transistor (302); one or more gate pads (373H) formed over the chip upper surface (101s) and electrically connected to a gate electrode (24H) of the high-side transistor (302); a plurality of source pads (371L) formed over the chip upper surface (101s) and electrically connected to a source electrode (28L) of the low-side transistor (303); a plurality of drain pads (372L) formed over the chip upper surface (101s) and electrically connected to a drain electrode (30L) of the low-side transistor (303); and a gate pad (373L) formed over the chip upper surface (101s) and electrically connected to a gate electrode (24L) of the low-side transistor (303),
wherein the plurality of source pads (371H) and the plurality of drain pads (372H) are each disposed in a region on one side (toward a +Y-axis direction) of a first direction on the chip upper surface (101s) so as to be arranged alternately in a second direction (X-axis direction) orthogonal to the first direction on the chip upper surface (101s),
wherein the plurality of source pads (371L) and the plurality of drain pads (372L) are each disposed in a region on the other side (toward a −Y-axis direction) of the first direction on the chip upper surface (101s) so as to be arranged alternately in the second direction (X-axis direction) on the chip upper surface (101s),
wherein the plurality of source pads (371L) are disposed so as to be arranged at intervals on the other side (toward the −Y-axis direction) of the first direction on the drain pad (372H), and
wherein the plurality of drain pads (372L) are disposed so as to be arranged at intervals on the other side (toward the −Y-axis direction) of the first direction on the source pad (371H).

[Supplementary Note 14] The chip of Supplementary Note 13, wherein the gate pad (373H) is arranged closer to an outer periphery than the plurality of source pads (371H) and the plurality of drain pads (372H), and
wherein the gate pad (373L) is arranged closer to the outer periphery than the plurality of source pads (371L) and the plurality of drain pads (372L).

A thickness of the semiconductor substrate (12) included in the chip recited in Supplementary Notes 13 and 14 and the material forming the semiconductor substrate (12) are not particularly limited.

According to the nitride semiconductor module of the present disclosure, it is possible to enhance heat dissipation.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A nitride semiconductor module, comprising:
a chip including at least one transistor,
wherein the chip includes:
a semiconductor substrate including a substrate upper surface and a substrate lower surface facing an opposite side of the substrate upper surface;
an electron transit layer formed over the substrate upper surface of the semiconductor substrate and made of GaN; and
an electron supply layer formed over the electron transit layer and made of GaN having a larger band gap than the electron transit layer,
wherein the at least one transistor includes a gate electrode, a source electrode, and a drain electrode, which are formed over the electron supply layer, and
wherein the semiconductor substrate is a GaN substrate having a thickness of 100 μm or less.

2. The nitride semiconductor module of claim 1, wherein the at least one transistor includes a plurality of transistors, and
wherein the chip includes the plurality of transistors.

3. The nitride semiconductor module of claim 1, further comprising:
a sealing member configured to cover the chip,
wherein the nitride semiconductor module includes a module upper surface formed of the sealing member and facing a same side as the substrate upper surface, and a module lower surface formed of the sealing member and facing a same side as the substrate lower surface, and
wherein a thickness of the semiconductor substrate is thinner than a distance from an upper surface of the electron supply layer to the module upper surface.

4. The nitride semiconductor module of claim 1, further comprising:
a sealing member configured to cover the chip,
wherein the nitride semiconductor module includes a module upper surface formed of the sealing member and facing a same side as the substrate upper surface, and a module lower surface formed of the sealing member and facing a same side as the substrate lower surface, and
wherein a chip lower surface of the chip is located closer to the module lower surface than the module upper surface in a thickness direction of the semiconductor substrate.

5. The nitride semiconductor module of claim 1, further comprising:
a sealing member configured to cover the chip,
wherein the nitride semiconductor module includes a module upper surface formed of the sealing member and facing a same side as the substrate upper surface, and a module lower surface formed of the sealing member and facing a same side as the substrate lower surface, and
wherein the nitride semiconductor module further comprises a heat dissipation member installed at the substrate lower surface and exposed to the module lower surface.

6. The nitride semiconductor module of claim 5, wherein the heat dissipation member has a thickness of 150 μm or less.

7. The nitride semiconductor module of claim 1, wherein the electron transit layer is a GaN layer, and
wherein the electron supply layer is an AlGaN layer.

8. The nitride semiconductor module of claim 1, wherein the at least one transistor includes a gate layer formed over the electron supply layer and made of GaN containing an acceptor type impurity, and
wherein the gate electrode is formed over the gate layer.

9. The nitride semiconductor module of claim 8, wherein the electron transit layer is a GaN layer,
wherein the electron supply layer is an AlGaN layer, and
wherein the gate layer is a GaN layer containing the acceptor type impurity.

10. The nitride semiconductor module of claim 1, further comprising:
a control circuit configured to control an on/off operation of the at least one transistor.

11. The nitride semiconductor module of claim 2, further comprising:
a bridge circuit configured by using the plurality of transistors.

12. The nitride semiconductor module of claim 11, wherein the plurality of transistors constitute a half-bridge circuit including a high-side transistor and a low-side transistor connected in series with each other, and
wherein the nitride semiconductor module further comprises a control circuit configured to control on/off operations of the high-side transistor and the low-side transistor.
